(19) United States
(12) Patent Application Publication
(10) Pub. No.: US 2012/0187435 A1
(43) Pub. Date: Jul. 26, 2012

(54) METHOD FOR MANUFACTURING A STRUCTURE WITH A TEXTURED SURFACE AS A MOUNTING FOR AN ORGANIC LIGHT-EMITTING DIODE DEVICE, AND OLED STRUCTURE WITH A TEXTURED SURFACE

(75) Inventors: René Gy, Bondy (FR); Stéphanie Pelletier, Paris (FR); Michele Schiavoni, Paris (FR); François-Julien Vermersch, Paris (FR)

(73) Assignee: Saint-Gobain Glass France, Coubevoie (FR)

(21) Appl. No.: 13/260,976

(22) PCT Filed: Apr. 2, 2010
(86) PCT No.: PCT/FR2010/050639

§ 371 Date: Dec. 22, 2011

(30) Foreign Application Priority Data
Apr. 2, 2009 (FR) 0952131

(51) Int. Cl. H01L 51/52; B32B 3/30; C03C 17/04; C03C 23/00; C03C 17/06

(52) U.S. Cl. 257/98; 65/60.1; 65/23; 65/60.2; 428/152; 257/E51.018; 257/40

(57) ABSTRACT

A production method and a structure having a textured surface forming the support for an organic-light-emitting-diode device, which structure is provided on a transparent substrate made of mineral glass on which is optionally deposited an interface film made of mineral glass, the profile of the texture of the surface comprising protrusions and troughs which are defined by an FT or a roughness parameter Rdq such that the protrusions are not too pointed and such that an increase in the extraction efficiency is ensured. The method especially consists in depositing on the glass substrate a coating film and in ensuring a contraction of the assembly by heating and cooling.

The invention relates to a method for manufacturing a structure having a textured surface provided on a transparent substrate made of mineral glass supporting an organic-light-emitting-diode device, and such a structure.

An OLED, for organic light-emitting diode, comprises an organic light-emitting material or a multilayer of organic light-emitting materials, and is framed by two electrodes, one of the electrodes, generally the anode, consisting of the one associated with the glass substrate and the other electrode, the cathode, being arranged on the organic materials opposite the anode.

The OLED is a device that emits light via electroluminescence using the recombination energy of holes injected from the anode and electrons injected from the cathode. In the case where the anode is transparent, the emitted photons pass through the transparent anode and the glass substrate supporting the OLED so as to supply light outside the device.

OLEDs are generally used in display screens or more recently in lighting devices, however with different constraints.

For a lighting system, the light extracted from the OLED is “white” light because certain or even all of the wavelengths of the visible spectrum are emitted. The light must furthermore be emitted uniformly. In this respect a Lambertian emission is more precisely spoken of, i.e. obeying Lambert's law, and characterized by a photometric luminance that is equal in all directions.

Moreover, OLEDs have low light-extraction efficiencies: the ratio between the light that actually exits from the glass substrate and that emitted by the light-emitting materials is relatively low, about 0.25.

This phenomenon is especially explained by the fact that a certain number of photons remain trapped between the cathode and the anode.

Solutions are therefore sought to improve the efficiency of OLEDs, namely to increase the extraction efficiency while supplying white light that is as uniform as possible. The term “uniform” is, in the remainder of the description, understood to mean uniform in intensity, color and in space.

It is known to provide, at the glass-anode interface, a periodically protruding structure that forms a diffraction grating and thus increases the extraction efficiency.

Document US 2004/0227462 presents a diffractive optical solution having a textured, transparent OLED substrate supporting the anode and the organic film. The surface of the substrate thus has an alternation of protrusions and troughs the profile of which is followed by the anode and the organic film deposited above. The profile of the substrate is obtained by applying a mask made of photoresist to the surface of the substrate, the pattern of which mask corresponds to that sought for the protrusions, and then etching the surface through the mask.

However, such a method is not easy to implement industrially over large substrate areas, and is above all too expensive, especially for lighting applications.

Electrical defects are furthermore observed in the OLEDs.

The invention therefore provides a method for manufacturing a substrate, in particular for a polychromatic (white) OLED, which simultaneously ensures increased extraction efficiency, sufficiently uniform white light and increased reliability.

One subject of the invention is therefore a method for producing a structure having a textured surface forming the support for an organic-light-emitting-diode device, the structure being provided on a transparent substrate made of mineral glass coated with an optional interface film made of mineral glass, the profile of the texture consisting of protrusions and troughs, the method comprising, to form the textured surface:

depositing a coating film, preferably an essentially inorganic coating film, on one of the main faces of the substrate, preferably over substantially all its area, or on said optional interface film, respectively, the coating film having a thickness smaller than or equal to 300 nm, preferably smaller than or equal to 100 nm, or even smaller than or equal to 50 nm, and being at least 10 times thinner, preferably at least 100 times thinner, than the substrate or said interface film, respectively;

contracting the substrate or the interface film, respectively, by sufficiently increasing the temperature up to a heating temperature T1 higher than the glass transition temperature Tg of the glass of the substrate or of the optional interface film, respectively, and by cooling the substrate or the optional interface film, respectively, the cooling taking place after the deposition of the coating film, and the difference between the free thermal contraction ε1 of the glass of the substrate or the optional interface film, respectively, and the free thermal contraction ε2 of the coating film, from the heating temperature T1 down to the glass transition temperature Tg, given by the formula ε1−ε2=(α1−α2)(T1−Tg), where α1 is the average linear thermal expansion coefficient of the glass above Tg and α2 is the average linear thermal expansion coefficient of the coating film above Tg, is at least 0.1%, preferably larger than 0.3%, or even larger than or equal to 0.55%.

Because it is periodic, the grating of the prior art optimizes the increase in extraction efficiency around a certain wavelength but does not promote white light emission; on the contrary, it has a tendency to select certain wavelengths and will emit for example more in the blue or the red.

In contrast, the textured profile obtained by the method of the invention provides protrusions the characteristic size of which, in terms of period and depth, are particularly suited to extracting light from an OLED.

Furthermore, protrusions that are too pointed, with angles that are too sharp, run the risk of causing electrical contact between the anode and the cathode, thus degrading the OLED.

To define the surface, it is preferable to introduce:

the well-known roughness parameter Rdq, which indicates the average slope, and to set a maximum value; and

optionally the well-known roughness parameter Rmax, which indicates the maximum height, and set a maximum value, optionally in addition to a minimum value, so as to promote extraction.

Thus, in one preferred embodiment, the contraction is such that the textured surface of the structure is defined by a roughness parameter Rdq smaller than 1.5°, preferably smaller than 1°, or even smaller than or equal to 0.7°, and preferably a roughness parameter Rmax larger than or equal to 20 nm, and optionally smaller than 100 nm, over an analysis area of 5 μm by 5 μm, for example with 512 measurement points.

The analysis area is suitably chosen depending on the roughness to be measured. The roughness parameters of the surface are preferably measured using an atomic force microscope (AFM).

The method can also ensure that the structure is such that at any point on its textured surface, the angle formed by the tangent at any point on the profile to the normal to the substrate is larger than 30°, preferably larger than 45°.

By virtue of this method a texture (typically creases) is given to a glass-based structure in a way that is both simple and that may potentially be applied over large areas.

Furthermore, if it is desired not to remove the coating film after creasing, said coating film does not hinder the textured pattern obtained because its surface is substantially conformal: its creases are uniform and homogenous about the creasing of the glass substrate, both in the troughs of the creases and on the peaks and the sides of the creases.

According to one feature of the method of the invention, the temperature increase results from heating the substrate for the deposition of the coating film.

As a variant, the temperature increase, produced by heating to said heating temperature T1, occurs after the coating film has been deposited, and the method then comprises removing the coating film.

According to another feature, the temperature increase up to the heating temperature T1 is at least 100° C., preferably at least 300° C., higher than the glass transition temperature Tg.

The interface film, made of a glass frit having a glass transition temperature Tg′ lower than that Tg of the substrate, is preferably deposited by screen printing; this interface film is especially a glass frit having a glass transition temperature Tg′ lower than or equal to 500° C.

Advantageously, the coating film is deposited by CVD on the substrate at the heating temperature, on a glass lamination line, after the laminating operation, or on a float glass line, or on rework of the glass.

As a variant, the coating film is deposited on the substrate using a magnetron.

According to another feature of the method, the cooling occurs at room temperature, in an annealing lehr or under thermal tempering conditions.

The coating film, especially metal coating film, is removed by selective chemical etching between the film and the substrate or the optional interface film.

The method thus causes a contraction that forms an isotropic texture. In contrast, it forms an anisotropic texture by applying a unidirectional tensile stress at the same time as the cooling.

Another subject of the invention is a structure having a textured surface forming the support for an organic- light-emitting-diode device, the structure being provided on a transparent substrate made of mineral glass on which an interface film made of mineral glass is optionally deposited, the profile of the texture of the surface consisting of protrusions and troughs and being obtainable by the method defined above.

Most (even at least 70% and even 80% or more) of the protrusions of such a profile take the form of creases (preferably with substantially rounded summits) which:

are elongate (especially relatively sinuous, each having a substantially constant width) and have a length greater than or equal to 2 μm and preferably greater than or equal to 5 μm, and a length less than 500 μm, even 300 μm, or more preferably less than 100 82 m, so as to limit the size of any regions where the creases all lie in the same direction;

are multidirectional, lying along at least two crossed directions, especially at least three directions, and the directions preferably forming an angle to one another greater than or equal to 10°, even 45°;

have a pitch or pseudo-period (i.e. have creases of substantially the same height and same width that repeat at least three times in a given direction) ranging from 200 nm to 4 μm, preferably ranging from 300 nm to 2 μm and more preferably ranging from 400 nm to 700 nm;

preferably have a maximum number in one and the same given direction lower than 100 times the largest pseudo-period, preferably lower than 50 times, more preferably lower than 20 times;

have a submicron-sized maximum height less than or equal to 300 nm, preferably less than 200 nm, even more preferably less than or equal to 100 nm; and

preferably have a minimum height greater than or equal to 20 nm, even 30 nm, preferably greater than or equal to 50 nm.

The texture (which may be qualified here as creases) of the invention may moreover be defined by its Fourier transform.

Another subject of the invention is thus a structure having a textured surface forming the support for an organic-light-emitting-diode device, which structure is provided on a transparent substrate made of mineral glass on which an interface film made of mineral glass is optionally deposited, the profile of the texture of the surface consisting of protrusions and troughs and being obtainable by the method defined above. The Fourier transform, denoted “FT”, of the textured surface furthermore has in at least one direction a frequency k′=2π/λ′ such that:

the modulus of FT(k′)>0.75×the modulus of FT(k′/2) and preferably the modulus of FT(k′)>the modulus of FT(k′/2);

the modulus of FT(k′)>the modulus of FT(1.5 k′) and preferably the modulus of FT(k′)>2×the modulus of FT(1.5 k′); and

λ′ lies in the wavelength range from 200 nm to 2 μm, preferably 300 nm to 1 μm, preferably 400 nm to 700 nm.

Generally, the FT of a random texture does not have a peak, but the FT has a shape that decreases with k.

The signature of the textures according to the invention, useful for OLEDs, is therefore the following:

the presence of a (pseudo-) period;

the FT remains fairly flat as k increases and then abruptly decreases at even higher k values; and

preferably the FT passes through a maximum and then abruptly decreases at even higher k values.

30

This texture is suited to OLEDs because it has a minimum number of ineffectual frequencies. Normally, in a random texture, the FT decreases slowly. To have a certain energy at the frequency k′, it is necessary to have energy at all the frequencies below k′, and there is then still energy at higher frequencies (slow decrease in the FT). This often comprises textures having very great protrusions or peak-to-valley heights, incompatible with OLEDs.

In the texture according to the invention, there is not energy at all frequencies, in particular there is as little energy as possible at low frequencies. This makes it possible to have much more energy at the frequency appropriate for light extraction, without having great peak-to-valley heights.

Thus, another subject of the invention is a structure having a textured surface forming the support for an organic-light-emitting-diode device, which structure is provided on a transparent substrate made of mineral glass on which an interface film made of mineral glass is optionally deposited, the profile of the texture of the surface consisting of protrusions and troughs and being obtainable by the method defined above. The Fourier transform FT furthermore has a pseudo-period that is centered on a value k′ such that k′=2π/λ′, where λ′ lies in the wavelength range between 200 nm and 2 μm, preferably between 300 nm and 1 μm, and in particular between 400 nm and 700 nm, and that varies about this value over a range Δk defined as the full-width at half-maximum of the peak corresponding to the difference between k″=2π/λ″ and k′″=2π/λ′″, the difference |λ′−λ′″| lying between 100 nm and 2 μm, preferably between 200 nm and 1000 nm, and in particular between 250 nm and 500 nm.

In addition, the structure obtained by the method of the invention provides creases lying along a multitude of directions parallel to the surface of the substrate. This multidirectional arrangement defines the isotropic character of the structure. The structure thus has an isotropy percentage.

The isotropy percentage may be calculated in the following way:
a profile is drawn passing through the center of the Fourier transform for a multiplicity of angles, 100 profiles every 3.6° for example;
a check is carried out to verify that each of the profiles extracted has a peak centered on a value k′ such that k′=2π/λ′, where λ′ lies in the wavelength range between 200 nm and 2 μm, preferably between 300 nm and 1 μm, and in particular between 400 nm and 700 nm, and that varies about this value over a range Δk defined as the full-width at half-maximum of the peak corresponding to the difference between k″=2π/λ″ and k′″=2π/λ′″; the difference |λ′−λ′″| lying between 100 nm and 2 μm, preferably between 200 nm and 1000 nm, and in particular between 250 nm and 500 nm; and

the number n of profiles of the 100 that meet the above criterion is counted so as to derive the isotropy percentage n/100 therefrom.

The isotropy percentage is at least 10%, preferably higher than 30%, and in particular higher than 60%. The light extracted is therefore spatially uniform.

The profile of the texture of the invention is preferably approximated by a “quasi-periodic” curve. This profile depends on the thickness of the coating film and on its nature and on the method for manufacturing the texture, which is provided by the invention.

According to the invention, the pitch separating two protrusions is quasi-periodic with a period approximately equal to the wavelength of the light i.e. between 200 nm and 2 μm, preferably between 300 nm and 1 μm, and in particular between 400 nm and 700 nm for visible light. However, advantageously, according to the invention, a certain wavelength range is obtained about this periodicity so as thus to provide a wider passband. This is what is meant by a “quasi-periodic” profile. More details on this profile will be given below with regard to its characterization using the Fourier transform.

The texture of the structure, the way in which this profile is obtained and the nature of the coating film are features that when combined further optimize the light extraction and uniformity of this light.

In a preferred embodiment, the textured surface of the structure is defined by most points having a tangent that makes an angle to a normal to the opposite face of the textured surface larger than or equal to 45°, and/or defined by a roughness parameter Rdq smaller than 1.5°, preferably smaller than 1°, or even smaller than or equal to 0.7°, and preferably a roughness parameter Rmax larger than or equal to 20 nm, and optionally smaller than 100 nm, over an analysis area of 5 μm by 5 μm, for example with 512 measurement points.

The coating film may preferably:

be essentially inorganic, especially so as to have a good thermal withstand; and/or

be a dielectric (in the sense that it is a non-metal) and preferably an electrical insulator (in general having a bulk electrical resistivity, such as known in the literature, higher than 10⁹ Ω·cm) or a semiconductor (in general having a bulk electrical resistivity, such as given in the literature, higher than 10⁻³ Ω·cm and lower than 10⁹ Ω·cm); and/or

not noticeably alter the transparency of the substrate; for example, the substrate coated with this film may have a light transmittance T_{L} higher than or equal to 70%, even 80%.

According to one advantageous feature, the coating film is a dielectric, especially a refractory ceramic, in particular Si₃N₄, SiO₂, TiO₂, ZnO, SnZnO or SnO₂. The dielectric film has a refractive index higher than or equal to 1.8 and preferably lower than or equal to 2.

A coating film made of a refractory and/or noble metal, such as Zr, Ti, Mo, Nb, W, Si, Al, Au, Pt and their alloys, is also advantageous, especially in the case where it is desired to remove the coating, because such a film is generally easier to remove from the surface of glasses than a ceramic film.

According to yet another feature, the interface film is a film obtained from a molten glass frit preferably having a glass transition temperature Tg′ lower than or equal to 600° C., or even lower than or equal to 500° C.

Finally, another subject of the invention is an organic-light-emitting-diode device incorporating the structure defined above or obtained by the method of the invention. The device also comprises a first transparent electrically conductive coating forming a first (lower) electrode and deposited on the textured face of the structure, an OLED system based on one or more organic films deposited on the first electrode, and a second electrically conductive coating that forms a second (upper) electrode and is deposited on the OLED system.

Advantageously, the first electrically conductive coating has a surface that substantially conforms to the surface of the structure and has a refractive index higher than or equal to that of the coating film.

The OLED may form a lighting panel, or a backlight (substantially white and/or uniform) especially having a (solid) upper-electrode area larger than or equal to 1×1 cm², even as large as 5×5 cm² and even 10×10 cm² or larger.

Thus, the OLED may be designed to form a single lighting panel (with a single electrode area) emitting (substantially white) polychromatic light or a multitude of lighting panels (having a plurality of electrode areas) emitting (substantially white) polychromatic light, each lighting panel having a (solid) electrode area larger than or equal to 1×1 cm², even as large as 5×5 cm², 10×10 cm² or larger.

Thus in an OLED according to the invention, especially for lighting, it is possible to choose a nonpixelated electrode. It therefore differs from an electrode for a display-screen (LCD, etc.) formed from three juxtaposed, generally very small pixels, each emitting a given, almost monochromatic light (typically red, green or blue).

The OLED system may be able to emit a polychromatic light defined, at 0°, by the (x1, y1) coordinates in the XYZ 1931 CIE color space, coordinates given therefore for light incident at a right angle.

The OLED may be back emitting and optionally also front emitting depending on whether the upper electrode is reflective or, respectively, semireflective or even transparent (especially having a T_{L} comparable to the anode, typically higher than 60% and preferably higher than or equal to 80%).

The OLED system may be able to emit (substantially) white light, having coordinates as close as possible to (0.33; 0.33) or (0.45; 0.41), especially at 0°.

To produce the substantially white light several methods are possible: component mixture (red, green and blue emission) in a single film; a multilayer, on the face of the electrodes, of three organic structures (red, green and blue emission); or two organic structures (yellow and blue).

The OLED may be able to produce as output (substantially) white light, having coordinates as close as possible to (0.33; 0.33) or (0.45; 0.41), especially at 0°.

The device may be part of a multiple glazing unit, especially glazing comprising a vacuum cavity or a cavity filled with air or another gas. The device may also be monolithic, comprising a monolithic glazing pane so as to be more compact and/or lighter.

The OLED may be bonded, or preferably laminated using a lamination interlayer, with another planar substrate, called a cap, which is preferably transparent, such as a glass, especially an extra-clear glass being used.

The invention also relates to the various applications that may be found for these OLEDs that are used to form one or more transparent and/or reflective (mirror function) light-emitting surfaces that are placed externally and/or internally.

The device may form (alternatively or cumulatively) a lighting system, a decorative system, or an architectural system etc., or a signaling display panel, for example a design, logo or alphanumeric sign, especially an emergency exit sign.

The OLED may be arranged so as to produce a uniform polychromatic light, especially for a uniform lighting, or to produce various light-emitting regions, having the same intensity or different intensities.

When the electrodes and the organic structure of the OLED are chosen to be transparent, it is in particular possible to produce a light-emitting window. The improvement in the illumination of the room is then not produced to the detriment of the transmission of light. Furthermore, by limiting reflection of light, especially from the external side of the light-emitting window, it is also possible to control the reflectance level for example so as to meet anti-dazzle standards in force for the curtain walling of buildings.

More widely, the device, especially transparent in part(s) or everywhere, may be:
intended for use in a building, such as for a light-emitting external glazing unit, a light- emitting internal partition or a (or part of a) light-emitting glazed door, especially a sliding door;
intended for use in a means of transport, such as for a light-emitting roof, a (or part of a) light-emitting side window, a light-emitting internal partition for a terrestrial, maritime or aerial vehicle (automobile, truck, train, airplane, boat, etc.);
intended for use in a domestic or professional setting such as for a bus shelter panel, a wall of a display cabinet, a jeweler's display case or a shop window, a wall of a greenhouse, a light-emitting tile;
intended for use as an internal fitting, such as for a shelf or furniture element, a front face for an item of furniture, a light-emitting tile, a ceiling light or lamp, a light-emitting refrigerator shelf, an aquarium wall; or
intended for backlighting of a piece of electronic equipment, especially a display screen, optionally a double screen, such as a television or computer screen or a touch screen.

OLEDs are generally separated into two broad families depending on the organic material used.

If the electroluminescent films are small molecules, SM-OLEDs (small molecule organic light-emitting diodes) are spoken of. Generally, the structure of an SM-OLED consists of a hole-injection-film multilayer (HIF), a hole-transporting film (HTF), a light-emitting film and an electron-transporting film (ETF).

Examples of organic light-emitting multilayers are for example described in the document entitled “four wavelength white organic light emitting diodes using 4,4′-bis-[carbazoyl-(9)]-stilbene as a deep blue emissive layer” C. H. Jeong et al., published in Organic Electronics 8 (2007) pages 683-689.

If the organic light-emitting films are polymers, PLEDs (polymer light-emitting diodes) are spoken of.

The present invention is now described using purely illustrative examples that in no way limit the scope of the invention, and using the appended drawings, in which:

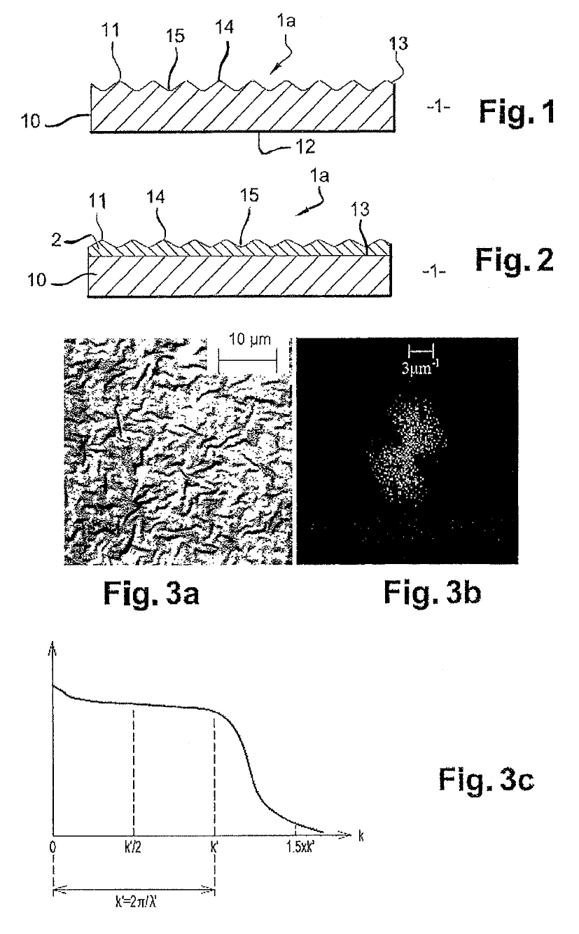

FIG. 1 shows a schematic cross section through a textured structure according to the invention;

FIG. 2 is a variant of FIG. 1;

FIG. 3a shows an optical micrograph of the textured surface of the structure in a first embodiment of the invention;

FIG. 3b shows the Fourier transform of the view in FIG. 3a;

FIG. 3c illustrates the profile of the Fourier transform shown in FIG. 3b;

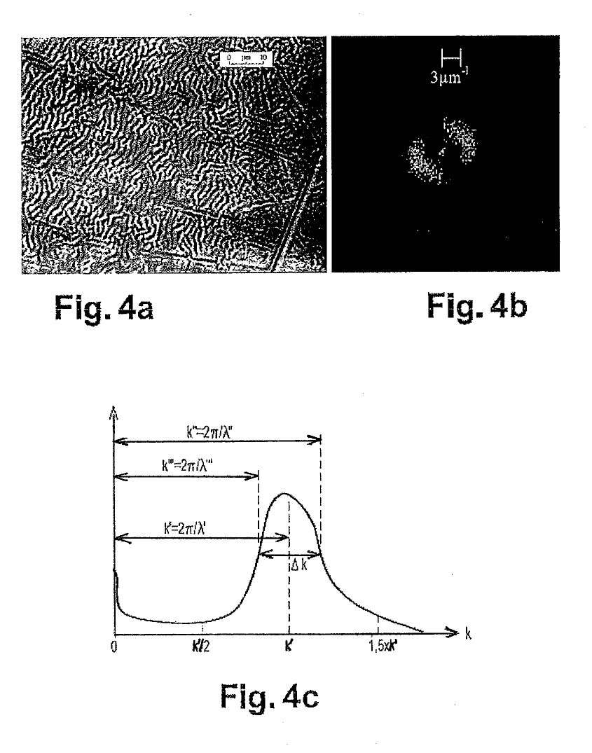

FIG. 4a shows an optical micrograph of the textured surface of the structure in a second embodiment of the invention;

FIG. 4b shows the Fourier transform of the view in FIG. 4a;

FIG. 4c illustrates the profile of the Fourier transform shown in FIG. 4b;

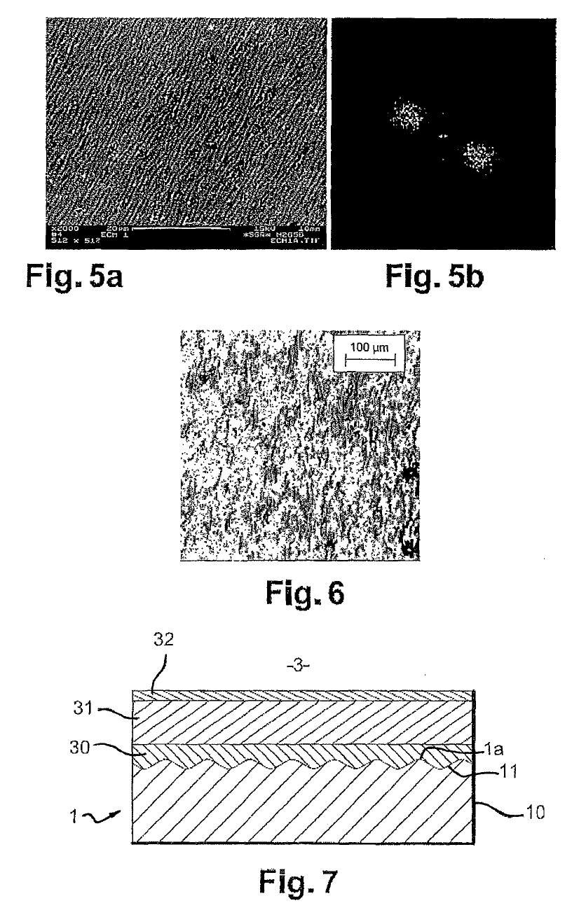

FIG. 5a is a scanning electron micrograph of anisotropic and quasi-periodic texturing of the structure in a third embodiment of the invention;

FIG. 5b shows the Fourier transform of the view in FIG. 5a;

FIG. 6 is an optical micrograph of an exemplary texture having an interface film that is not covered by the scope of the invention and is also not part of the prior art; and

FIG. 7 is a schematic cross-sectional view of an OLED according to the invention.

FIG. 1 illustrates a preferably isotropic and quasi-periodic textured structure 1 according to the invention. It has, on one of its main faces la, a texture that is intended, when photons strike this textured face and pass through said structure, to reflect less light, so as to optimize the final extraction efficiency, and so as to obtain a white light by minimizing its extraction in wavelength ranges that are too narrow, and light that is as uniform as possible, in particular in space.

The structure 1 comprises, once produced using the method of the invention, a substrate 10 made of transparent mineral glass, optionally a transparent coating film 11, which is a film that has specific properties (described below on the basis of the examples), and potentially, in one variant, a transparent interface film 2 made of mineral glass and deposited between the coating film and the substrate (FIG. 2).

The substrate 10 is made of mineral glass and is between 0.7 mm and 3 mm in thickness. It has a first main face 12 and an opposed second main face 13 that is coated, over all of its area, with the coating film 11, when the latter has not been removed after the creases have been obtained, or with the interface film 2 in a variant embodiment.

The structure 1 is textured on its face la so that it comprises a multitude of protrusions 14 forming an alternation of troughs 15.

As may be seen in FIG. 1, the structure 1 comprises only the coating film 11, the texture being reproduced in the thickness of the coating film and to a certain depth in the glass substrate.

Thus, the second face 13 of the glass substrate is not flat and has a profile that is identical to that of the coating film 11, one closely following the other.

The thickness of the coating film 11 is uniform over its entire area and is at least 5 nm. In order to have the desired structure, the thickness depends on the nature of the film and also on the amount that the hot glass or the viscous interface film 2, between the glass and the coating film 11, is made to contract.

The inventors have demonstrated that it is essential for the external surface of the structure that is to receive the electrode to be free from any sharp points.

Thus, to guarantee that this requirement is met, the textured surface is defined by a roughness parameter Rdq smaller than 1.5°, and preferably a roughness parameter Rmax smaller than or equal to 100 nm over an analysis area of 5 μm by 5 μm, preferably measured by AFM.

The tangent at a majority of points on the textured surface may also make, to a normal to the opposed planar face, an angle larger than or equal to 30°, and preferably at least 45°.

The heating temperature for the contraction according to the method of the invention is at least 100° C. to 300° C. higher than the glass transition temperature of the glass, a temperature corresponding to a sufficiently low viscosity for the substrate or for the interface film made of mineral glass. Examples of preferred materials for the coating film 11 are Si₃N₄ or SiO₂.

The face 13 of the glass substrate and the coating film 11, which are intimately attached to each other, is thus a unitary assembly that has an identical profile.

In the variant embodiment in FIG. 2, the face 13 of the glass substrate remains flat, the texture obtained by virtue of the coating film 11 is produced on the interface film 2, as will be seen below in the description of the manufacturing method.

The profile obtained by contraction of the interface film 2 is thus produced throughout the thickness of the coating film 11 and throughout the thickness of said interface film. The face 13 of the substrate thus has a textured surface.

The profile of the texture is matched to the thickness of the coating film 11, to its nature and to the method for manufacturing the texture provided by the invention.

### EXAMPLE NO. 1 OF A TEXTURED STRUCTURE ACCORDING TO THE INVENTION

FIG. 3a shows an optical micrograph of a textured surface in a first embodiment of the invention.

A substrate made of soda-lime-silica glass was chosen having a thickness of about a millimeter, a glass transition temperature T_{g} equal to 550° C. and an average linear thermal expansion coefficient near 30×10⁻⁶ I K⁻¹ for temperatures higher than 550° C. (Tg).

The heating temperature T1 for the contraction of the substrate by cooling was chosen to be equal to 750° C.

The coating film was deposited on the unheated glass substrate using a magnetron vacuum process. This film was made of ZnO, having a thickness equal to 50 nm and an average linear thermal expansion coefficient near 60×10⁻⁷ K⁻¹ for temperatures higher than 550° C. (Tg).

The difference between the free thermal contraction ε1 of the glass and the free thermal contraction ε2 of the coating film, from the heating temperature T1 down to the glass transition temperature Tg, was therefore 0.48%. The calculation was performed using the formula provided above in the introductory part of the description.

From a topographical point of view the submicron-sized protrusions mainly took the form of creases that:

were elongate, more or less sinuous, and each with a substantially constant width;

were between 4 and 10 μm long;

were multidirectional (along a plurality of directions), with directions making angles of at least 10°, even 20° or more; and

had a pitch (pseudo-period), separating two creases, lying between 0.7 μm and 2 μm.

FIG. 3b corresponds to the Fourier transform (FT) of the image shown in FIG. 3a. The Fourier transform indicates that the creases are practically isotropic.

Specifically, what is seen is an FT that is symmetric relative to the center and that decreases as the wavevector k increases. The FT does not have perfect rotational symmetry, meaning that the texture is oriented slightly.

The decrease in the FT is quite slow until a value of 5 μm⁻¹is reached. It then becomes abrupt, reaching a value of approximately zero at 8 μm⁻¹.

FIG. 3c illustrates the profile of the Fourier transform of the view in FIG. 3b.

The Fourier transform of the textured surface has in at least one direction a frequency k′=2π/λ′, here equal to 3.5 μm⁻¹, i.e. λ′=1.8 μm.

The ratio: modulus of FT(k′)/modulus of FT(k′/2)=1.

The ratio: modulus of FT(k′)/modulus of FT(1.5 k′)=4.

The isotropy percentage was about 80%.

The isotropy percentage was calculated as described above in the description.

### EXAMPLE NO. 2 OF A TEXTURED STRUCTURE ACCORDING TO THE INVENTION

FIG. 4a shows an optical micrograph of a textured surface in a second embodiment of the invention.

A substrate made of aluminosilicate glass was chosen having a thickness of about a millimeter, a glass transition temperature Tg equal to 690° C. and an average linear thermal expansion coefficient near 30x10⁻⁶ K⁻¹ for temperatures higher than 690° C. (Tg).

The heating temperature T1 for the contraction of the substrate by cooling was chosen to be equal to 900° C.

The coating film was deposited on the unheated glass substrate using a magnetron vacuum process. Said film was made of Si0₂ having a thickness equal to 50 nm and an average linear thermal expansion coefficient near 5×10⁻⁷ K⁻¹ for temperatures higher than 690° C. (Tg).

The difference between the free thermal contraction ε1 of the glass and the free thermal contraction ε2 of the coating film, from the heating temperature T1 down to the glass transition temperature Tg, was therefore 0.62%.

From a topographical point of view the submicron-sized protrusions mainly took the form of creases that:

were elongate, more or less sinuous, and each with a substantially constant width;

were between 4 and 15 μm long;

were multidirectional (along a plurality of directions), with directions making angles of at least 10°, even 20° or more; and

had a pitch (pseudo-period), separating two creases, lying between 1.5 μm and 2.5 μm.

FIG. 4b corresponds to the Fourier transform of the image shown in FIG. 4a. As in the preceding example, the Fourier transform indicates that the creases are practically isotropic.

Specifically, what is seen is an FT that is symmetric relative to the center. The FT has a ring about the center, signature of the texture indeed having a precise pitch. The maximum of the FT is located at values of about 4.2 μm⁻¹. The FT does not have perfect rotational symmetry, meaning that the texture of FIG. 4a is oriented slightly.

The decrease in the FT was quite abrupt for higher values of the wavevector k, reaching a value of approximately zero at 9 μm⁻¹.

Moreover, the inventors have demonstrated that not only should the profile be sufficiently isotropic, but also preferably a quasi-periodic.

Moreover, considering a cross section through the Fourier transform in any direction, passing through the center of the image in FIG. 4b, a profile is obtained for the Fourier transform having the shape of the curve in FIG. 4c.

The Fourier transform of the textured surface has in at least one direction a frequency k′=2π/λ′, here equal to 4.2 μm⁻¹, i.e. λ′=1.5 μm.

The ratio: modulus of FT(k′)/modulus of FT(k′/2)=3.5.

The ratio: modulus of FT(k′)/modulus of FT(1.5k′)=3.5.

The curve in FIG. 4c moreover has a substantially Gaussian-shaped peak. The separation of this peak from the origin 0 of the graph corresponds to the average period, i.e. the average pitch between two adjacent protrusions 14.

The profile is “quasi-periodic” in the sense that the peak is centered on a period value k′, and spreads over a width Δk considered to be the half-maximum of the peak. Consequently, if most of the protrusions are separated from one another by a period λ′ such that λ′=2π/k′, others are separated by a period λ″ such that k″=2π/λ″ with k″ varying about this value k′, and others still separated by a λ′″ such that k′″=2π/λ′″, with k′″ varying about this value k′.

This peak is centered on the value k′ such that k′=2π/λ′, where λ′ belongs to the wavelength range defined above, namely λ′ lies in the range [200 nm; 2 μm].

Moreover, the width Δk of this peak is optimized. Considering Δk as the full-width at half-maximum of the peak, which corresponds to the difference between k″=2π/λ″ and k′″=2π/λ′″, the difference |λ″−λ′″|, according to the invention, lies between 100 nm and 2 μm.

Consequently, the pitch separating the protrusions is centered on the wavelength value λ′ and varies in the range

$${λ}^{′} \pm \frac{\vert {λ}^{″} - {λ}^{″′} \vert}{2} .$$

In this way, it is possible, with a single texture, to cover the entire wavelength range of the light.

In the case of example 2, the following was obtained:

λ′=550 nm and |λ″−λ′″|=300 nm, thereby giving a range corresponding to 550 nm±150 nm, i.e. between 400 nm and 700 nm.

A texture with such a profile therefore covers the visible spectrum, ensuring that a white light is extracted and not a light reduced to a restricted wavelength range corresponding for example to a given color in the spectrum.

The isotropy percentage was about 75%.

### EXAMPLE NO. 3 OF A TEXTURED STRUCTURE ACCORDING TO THE INVENTION

FIG. 5a is a scanning electron micrograph of an anisotropic creasing substantially oriented along the same direction in a third embodiment of the invention. It was obtained by adding an anisotropic deformation to the glass substrate during the manufacturing method by applying a vertical tensile stress to the structure while it was still hot.

A substrate made of soda-lime-silica glass was chosen having a thickness of about one millimeter, a glass transition temperature Tg equal to 550° C. and an average linear thermal expansion coefficient near 30×10⁻⁶ K⁻¹ for temperatures higher than 550° C. (Tg).

The coating film was made of SnO₂ and deposited by CVD on the already hot substrate heated to a temperature of 800° C. (heating temperature T1 for the contraction of the substrate by cooling). Its thickness was 15 nm and its average linear thermal expansion coefficient was near 4.5×10⁻⁶ K⁻¹ for temperatures higher than 550° C. (Tg).

The difference between the free thermal contraction ε1 of the glass and the free thermal contraction ε2 of the coating film, from the heating temperature T1 down to the glass transition temperature Tg, was therefore 0.635%.

From a topographical point of view the submicron-sized protrusions mainly took the form of creases that:

were elongate, more or less sinuous, and each with a substantially constant width;

were between 2 and 5 μm long;

were multidirectional (along a plurality of directions), with the directions making angles of about 10°; and

had a pitch (pseudo-period), separating two creases, lying between 0.9 μm and 2.5 μm.

FIG. 5b corresponds to the Fourier transform (FT) of the image shown in FIG. 5a. The anisotropy may clearly be seen.

It is possible to see that the Fourier transform of the image (FIG. 5b) has a profile substantially in one direction.

The FT is symmetric about the center. The FT contains two clearly distinct spots that are symmetric about the center. This is a signature of a precise pitch in the texture and of a well-oriented texture. The maximum in the FT is located at values of about 5 μm⁻¹. The FT does not have rotational symmetry, meaning that the texture in FIG. 5a is oriented. The isotropy percentage is about 5%.

The decrease in the FT is quite abrupt for higher values of the wavevector k, reaching a value of approximately zero at 10 μm⁻¹.

The Fourier transform of the textured surface had in at least one direction a frequency λ′=2π/λ′ here equal to 5 μm⁻¹, i.e. λ′=1.25 μm.

The ratio: modulus of FT(k′)/modulus of FT(k′/2)=4.

The ratio: modulus of FT(k′)/modulus of FT(1.5 k′)=10.

### EXAMPLE NO 4, NOT ACCORDING TO THE INVENTION

FIG. 6 is an optical micrograph of an anisotropic creasing obtained on a substrate coated with an interface film.

The method used to produce the creases was the following: hot CVD deposition of a film of SnO₂, 100 nm in thickness, on a soda-lime glass coated with a film of a glass frit 10 μm in thickness, i.e. too thick to yield a texture according to the invention. The glass frit had a glass transition temperature Tg′ of 400° C. and the deposition was carried out at 600° C.

A texture was obtained that had a very high pitch relative to that desired for the application, typically about 20 μm. Moreover the texture had an orientation.

The textured structure of the invention is more particularly suited to incorporation thereof in an OLED, as schematically illustrated in FIG. 7.

OLED with Textured Structure

The OLED 3 comprised the textured structure 1, a first transparent electrically conductive coating 30 that formed an electrode and that was arranged on the textured face la of the structure provided with the coating film 11, a film 31 of organic material(s), and a second electrically conductive coating 32 that formed a second electrode and that had, preferably facing the organic film 31, a (semi)reflective surface intended to reflect light emitted by the organic film in the opposite direction i.e. that of the transparent substrate.

Light emitted by the organic film 31 passed through the textured structure 1 of the invention, exiting to the exterior of the device via the face 12 of the structure. The light thus had a high luminance and was uniform and isotropic. This was because the texture substantially increased the light extraction efficiency of the OLED and increased the diffraction of the photons, ensuring that colors of different wavelengths recombined through the thickness of the substrate 10, providing a uniform and isotropic white light.

The textured structure, preferably with an isotropic and quasi-periodic profile, was obtained by the manufacturing method of the invention which consisted in:

depositing on a substrate made of flat mineral glass a suitable coating film 11;

subjecting the substrate coated with the film to a heat treatment so as to crease the surface structure after cooling; and

optionally, after the creasing has been obtained, removing the coating film 11.

The use of the materials Si₃N₄, SiO₂, TiO₂, SnO₂ or ZnO is especially recommended for forming the coating film. Si₃N₄ is preferred for a light-emitting device such as an OLED, because advantageously it will directly form the first film of the multilayer electrode 30 of the OLED.

According to a first embodiment, the film 11 was deposited on a glass substrate 10 that was not heated, and the heat treatment consisted in heating the covered substrate and then cooling it.

The film was preferably deposited on the cold substrate using a magnetron.

The covered substrate was heated to a temperature T1 at least 100° C. (preferably 300° C.) higher than the glass transition temperature Tg of the glass.

According to a second embodiment, the film 11 was deposited on a glass substrate 10 that was hot, and the heat treatment consisted in cooling the covered substrate.

Before the film was deposited, the glass substrate was heated to a temperature at least 100° C. (preferably 300° C.) higher than the glass transition temperature.

In a variant of this second embodiment, the substrate was already hot, having a certain temperature T1 at least 100° C. (preferably 300° C.) higher than the glass transition temperature Tg of the glass because the film 11 was deposited directly on a glass lamination line, after the lamination operation, or on a float glass line, in the float bath, or else on uncoated glass heated on rework after its manufacture.

The film was preferably deposited on the hot substrate using CVD (chemical vapor deposition).

In the two embodiments, the cooling of the covered substrate was a natural cooling at room temperature, or even that of a thermal tempering or toughening. It was also possible to include a controlled cooling step during the cooling.

Finally, in the first embodiment of the cold-deposited film, it was possible to deposit beforehand a glass interface film 2 the glass transition temperature Tg′ of which was a lower temperature than that of the glass substrate, for example by at least 100° C.

For example, a glass frit having a glass transition temperature Tg′ of 400° C. was deposited by screen printing, the frit for example having a high alkaline and/or boron or even bismuth content.

The coating film 11 was then deposited using a magnetron, and the substrate and films were heated to a temperature higher than 550° C. The cooling of the whole was advantageously carried out by a thermal tempering.

The benefit of heating the substrate and films to a temperature lower than that necessary when the glass substrate was covered directly with the coating film was therefore lower energy consumption.

Furthermore, this variant embodiment deforms the glass substrate less.

Likewise, as a variant of the second embodiment, in order to avoid the need to deposit the film at a very high temperature, sometimes only obtained with difficulty in an industrial setting, it is advantageously possible as mentioned above to coat the surface of a glass with an interface film 2 having a glass transition temperature lower than that of the glass substrate, for example with a glass frit, and to heat the film during the deposition of the coating film. This is because it is generally easier to provide a glass frit having a low glass transition temperature than a (float) glass having a low glass transition temperature.

This method that, via contraction, gives the structure a textured profile with protrusions with slopes appropriate for an OLED is thus easy to implement and may be applied over large areas of glass.

1. A method for producing a structure having a textured surface forming a support for an organic-light-emitting-diode device, which structure is provided on a transparent substrate made of mineral glass coated with an optional interface film made of mineral glass, a profile of the texture comprising protrusions and troughs, the method comprising:
depositing a coating film on one of the main faces of the substrate or on said optional interface film, respectively, the coating film having a thickness smaller than or equal to 300 nm and being at least 10 times thinner than the substrate or said interface film, respectively;
contracting the substrate or the interface film, respectively, by sufficiently increasing the temperature up to a heating temperature T1 higher than a glass transition temperature Tg of the glass of the substrate or of the optional interface film, respectively, and by cooling the substrate or the optional interface film, respectively, the cooling taking place after the deposition of the coating film, wherein a difference between the free thermal contraction ε1 of the glass of the substrate or the optional interface film, respectively, and the free thermal contraction ε2 of the coating film, from the heating temperature T1 down to the glass transition temperature Tg given by the formula ε1−ε2=(α1−α2)(T1−Tg), where al is the average linear thermal expansion coefficient of the glass above Tg and α2 is the average linear thermal expansion coefficient of the coating film above Tg, is at least 0.1%.

2. The production method as claimed in claim 1, wherein the temperature increase results from heating the substrate for the deposition of the coating film.

3. The production method as claimed in claim 1, wherein the temperature increase, produced by heating to said heating temperature T1, occurs after the coating film has been deposited, and wherein the method comprises removing the coating film.

4. The production method as claimed in claim 1, wherein the temperature increase up to the heating temperature T1 is at least 100° C., preferably at least 300° C., higher than the glass transition temperature Tg.

5. The method as claimed in claim 1 wherein the interface film, made of a glass frit having a glass transition temperature Tg′ lower than that Tg of the substrate, especially a glass frit having a glass transition temperature Tg′ lower than or equal to 500° C., is deposited by screen printing.

6. The method as claimed in claim 1, wherein the coating film is deposited by CVD on the substrate at the heating temperature, on a glass lamination line, after a laminating operation, or on a float glass line, or on rework of the glass.

7. The method as claimed in claim 1, wherein the coating film is deposited on the substrate using a magnetron.

8. The method as claimed in claim 1, wherein the cooling occurs at room temperature, in an annealing lehr or under thermal tempering conditions.

9. The method as claimed in claim 1, wherein the coating film, especially metal coating film, is removed by selective chemical etching between the film and the substrate or the optional interface film.

10. The method as claimed in claim 1, wherein the contraction is such that at any point on the textured surface, an angle formed by a tangent at any point on the profile to a normal to the substrate is larger than 30°, preferably larger than 45°, and/or the textured surface of the structure is defined by a roughness parameter Rdq smaller than 1.5° over an analysis area of 5 μm by 5 μm.

11. The method as claimed in claim 1, wherein the contraction forms an isotropic texture.

12. The method as claimed in claim 1, wherein the contraction forms an anisotropic texture by applying a unidirectional tensile stress at the same time as the cooling.

13. A structure having a textured surface forming a support for an organic-light-emitting-diode device, which structure is provided on a transparent substrate made of mineral glass on which an interface film made of mineral glass is optionally deposited, a profile of the texture of the surface of comprising protrusions and troughs and being obtainable by the method according to claim 1, wherein most of the protrusions take the form of creases that:
are elongate and have a length greater than or equal to 2 μm and less than 500 μm;
are multidirectional, lying along at least two crossed directions;
have a pitch or pseudo-period ranging from 200 nm to 4 μm and that, in a given direction, have a maximum number lower than 100 times the largest pseudo-period; and
have a submicron-sized maximum crease height less than or equal to 300 nm.

14. A structure having a textured surface forming a support for an organic-light-emitting-diode device, which structure is provided on a transparent substrate made of mineral glass on which an interface film made of mineral glass is optionally deposited, a profile of the texture of the surface comprising protrusions and troughs and being obtainable by the method according to claim 1, wherein a Fourier transform FT of the textured surface has in at least one direction a frequency k′=2π/λ′ such that:
the modulus of FT(k′)>0.75×the modulus of FT(k′/2);
the modulus of FT(k′)>the modulus of FT(1.5 k′); and
lies in the wavelength range from 200 nm to 2 μm.

15. The structure having a textured surface provided on a substrate, as claimed in claim 14, wherein the Fourier transform FT of the textured surface has a pseudo-period that is centered on a value k′ such that k′=2π/λ′, where λ′ lies in the wavelength range between 200 nm and 2 μm, and that varies about this value over a range Δk defined as the full-width at half-maximum of the peak corresponding to the difference between k″=2π/λ″ and k′″=2π/λ′″, the difference |λ″−λ′″| lying between 100 nm and 2 μm.

16. The structure as claimed in claim 13, it wherein the structure has an isotropy percentage of at least 10%, preferably higher than 30%.

17. The structure as claimed in claim 13 wherein for most points on the textured surface a tangent and a normal to an opposite face of the textured surface make an angle larger than or equal to 45°, and/or the textured surface of the structure is defined by a roughness parameter Rdq smaller than 1.5° over an analysis area of 5 μm by 5 μm.

18. The structure as claimed in claim 13, comprising a coating film having a textured surface, said film being a dielectric, especially a refractory ceramic, such as comprising Si₃N₄, SiO₂ or TiO₂, or even SnO₂, ZnO or SnZnO.

19. The structure as claimed in claim 13, comprising a coating film having a textured surface, this film being a refractory and/or noble metal, selected from the group consisting of Zr, Ti, Mo, Nb, W, Si, Al, Au, Pt and their alloys.

20. The structure as claimed in claim 18, wherein the dielectric coating film has a refractive index higher than or equal to 1.8 and lower than or equal to 2.

21. The structure according to claim 13, wherein the interface film is a film obtained from a molten glass frit having a glass transition temperature Tg′ lower than or equal to 600° C., or even lower than or equal to 500° C.

22. An organic-light-emitting-diode device comprising the structure obtained by the method according to claim 1, comprising a first transparent electrically conductive coating forming a first electrode and deposited on the textured face of the structure, an OLED system based on one or more organic films deposited on the first electrode, and a second electrically conductive coating that forms a second electrode and is deposited on the OLED system.

23. The organic-light-emitting-diode device according to claim 22, wherein the first electrically conductive coating has a surface that substantially conforms to the surface of the structure and has a refractive index higher than or equal to that of the coating film.

24. An organic-light-emitting-diode device comprising:
the structure as claimed in claim 13;
a first transparent electrically conductive coating forming a first electrode and deposited on the textured face of the structure;
an OLED system based on one or more organic films deposited on the first electrode, and a second electrically conductive coating that forms a second electrode and is deposited on the OLED system.
